(19) United States
(12) Patent Application Publication
(10) Pub. No.: US 2017/0175254 A1
(43) Pub. Date: Jun. 22, 2017

(54) SUBSTRATE CARRIER THAT CARRIES A SUBSTRATE ON EACH OF TWO BROAD SIDES OF THE SUBSTRATE CARRIER THAT FACE AWAY FROM EACH OTHER

(71) Applicant: Aixtron SE, Herzogenrath (DE)

(72) Inventors: Alexandre JOUVRAY, Huntingdon (GB); David Eric RIPPINGTON, Suffolk (GB); Kenneth B. K. TEO, Cambridge (GB); Nalin L. RUPESINGHE, Cambridge (GB)

(21) Appl. No.: 15/128,070

(22) PCT Filed: Mar. 18, 2015
(86) PCT No.: PCT/EP2015/055641

§ 371 Date: Sep. 21, 2016

(30) Foreign Application Priority Data
Mar. 24, 2014 (DE) 10 2014 104 009.0

(51) Int. Cl. C23C 14/50; C23C 16/458

(52) U.S. Cl. CPC C23C 14/50; C23C 16/4582; C01B 31/0226; B82Y 30/00

(57) ABSTRACT

A substrate carrier is configured to be arranged in a CVD or PVD reactor, in particular for the deposition of carbon nanotubes or graphene. The substrate carrier has a first broadside surface and a second broadside surface facing away from the first broad-side surface. The first broadside surface and the second broadside surface of the substrate carrier each have a substrate accommodation zone. Fastening elements are provided within each of the substrate accommodation zones to secure a substrate or sections of a substrate to one or more of the broadside surfaces. A CVD reactor is further configured to receive the substrate carrier.

The invention relates to a substrate carrier and to a CVD reactor which interacts with the substrate carrier and in which the substrate carrier may be disposed. This herein is a CVD or PVD reactor, in particular for the deposition of carbon nanotubes. The substrate carrier forms two broad-side faces that face away from one another.

Devices for coating substrates are disclosed in DE 195 22 574 A1, U.S. 2010/0319766 A1, and U.S. 2013/0084235 A1. The substrates in part lie on substrate carriers; however, the substrates in part are also suspended freely between two mutually opposite gas-inlet elements. U.S. 2013/0089666 A1 describes a copper substrate that has two broad-side faces.

The invention relates to a device for the deposition of nanotubes of carbon. To this end, gaseous primary materials are placed in a processing chamber. This is performed by means of a gas-inlet element. A substrate which is disposed on a substrate carrier is located within the processing chamber. A carbon-containing process gas, for example CH₄, C₂H₄, C₂H₂, or C₆H₆ is introduced into the processing chamber. Devices for coating flexible substrates are also described inter alia in GB 2 458 776 A, or JP 2005-133165 A.

Moreover, substrate carriers which have substrate-receiving zones on two mutually opposite broad-side faces are known from DE 41 25 334 A1, DE 92 10 359 U1, DE 295 25 989 U1, and DE 40 36 449 A1.

The invention is based on the object of improving a device or parts of a device for the deposition of carbon nanotubes, graphene, or the like.

The object is achieved by the invention stated in the claims.

The substrate carrier according to the invention has two broad-side faces. The broad-side faces face away from one another. Each of the two broad-side faces forms one substrate-receiving zone. The substrate carrier is preferably a flat body which has one substrate-receiving zone on each of the two broad sides of said substrate carrier that face away from one another. This substrate-receiving zone may have a rectangular footprint. The body that forms the substrate carrier may be composed of quartz and have a maximum thickness of 10 mm. The minimum edge length of said body is preferably 100 mm. The substrate-receiving zone may be delimited by a periphery of the body. Said periphery is preferably a rounded periphery around which a central portion of a flexible substrate of, for example, Al, Ni, or Cu is placeable such that two end portions of the substrate may in each case bear on one of the two substrate-receiving zones. However, two mutually separate substrates may also be used, wherein in each case one substrate is fastened to one of the two broad sides of the substrate carrier by means of a fixing element. The fixing element may be formed by a plurality of clamps, screws, or other suitable elements by way of which the substrate, or a portion of the substrate, may be fixedly fastened to the broad-side faces. The substrate-receiving zone may moreover have peripheries that run so as to be transverse to the aforementioned peripheries. These peripheries may be transition zones in which the substrate-receiving zone transitions into a peripheral portion. The peripheral portion preferably forms a handling portion on which the substrate carrier may be gripped or guided. The handling portion preferably has windows. The windows may have a rectangular cross section. The windows may be gas-passage windows. However, said windows may also be used for manual handling. Said windows then form gripping windows. The windows may have mutually dissimilar sizes. The handling portion may moreover also form protrusions. These protrusions may protrude beyond the peripheral edge of the substrate-receiving zone, and serve inter alia for fastening the substrate carrier within a CVD or PVD reactor. The protrusions extend in the direction of planar extent and form peripheral portions in relation to which a peripheral edge of the receiving zone runs in a recessed manner. The spacing of two mutually opposite peripheral edges of the receiving zone is thus smaller than the spacing of two mutually opposite peripheries of two protrusions of the two handling portions that face away from one another. The reactor, or the processing chamber, respectively, may have guide elements which in particular have grooves in which grooves the protrusions of the handling portions engage. The protrusions of the handling portions thus form guide portions. The grooves herein have a groove depth that is smaller than the excess length of the protrusions in relation to the peripheral edge of the receiving zone. In consequence, the peripheral edge of the receiving zone is remote from the guide elements. One guide portion which in each case protrudes beyond the periphery of the substrate-receiving zone is preferably provided in each of the four corners of the substrate carrier. The CVD reactor may have a loading opening which extends in a vertical direction. In a vertical orientation, that is to say having one peripheral edge facing upward and having another peripheral edge facing downward, the substrate carrier may be pushed through the loading opening into the processing chamber of the reactor housing. The processing chamber has mutually opposite gas-inlet elements which extend in the vertical direction, each being in the form of a shower head, that is to say having a gas-exit area which has a multiplicity of uniformly distributed gas-exit openings. The abovementioned process gas may flow through the two mutually facing gas-exit areas into the processing chamber. By way of a chemical decomposition reaction, nanotubes are formed on the two broad-side faces of the substrate carrier that face away from one another, that is to say on the substrates bearing thereon. This is preferably a catalytic reaction which takes place at approximately 1000° C. on the surface of the substrate. Herein, nanotubes or graphene structures of carbon are formed that grow transversely to the plane of extent of the substrate.

One exemplary embodiment of the invention will be explained hereunder by means of appended drawings in which:

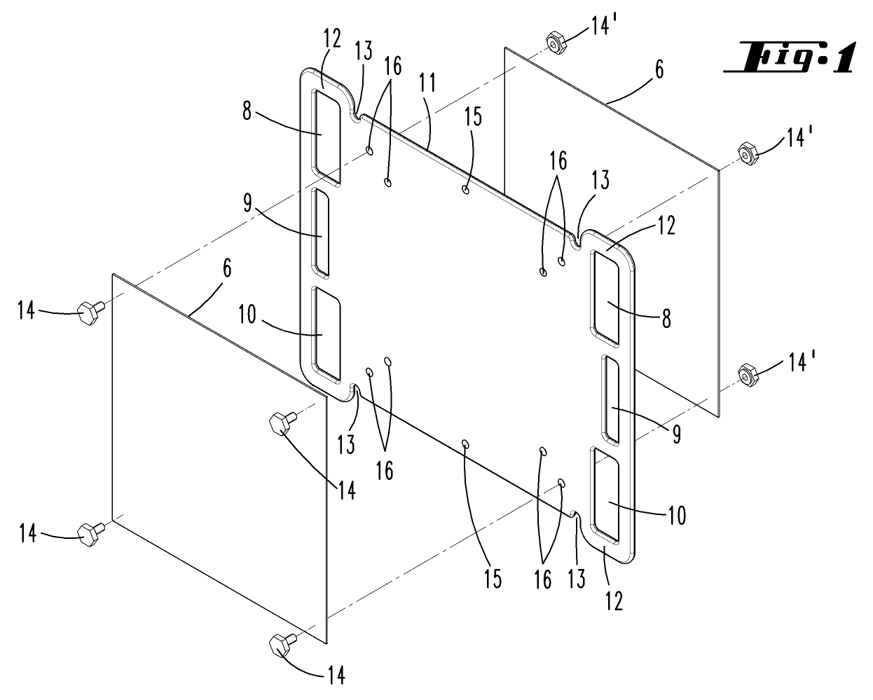

FIG. 1 shows an exploded illustration of a substrate carrier;

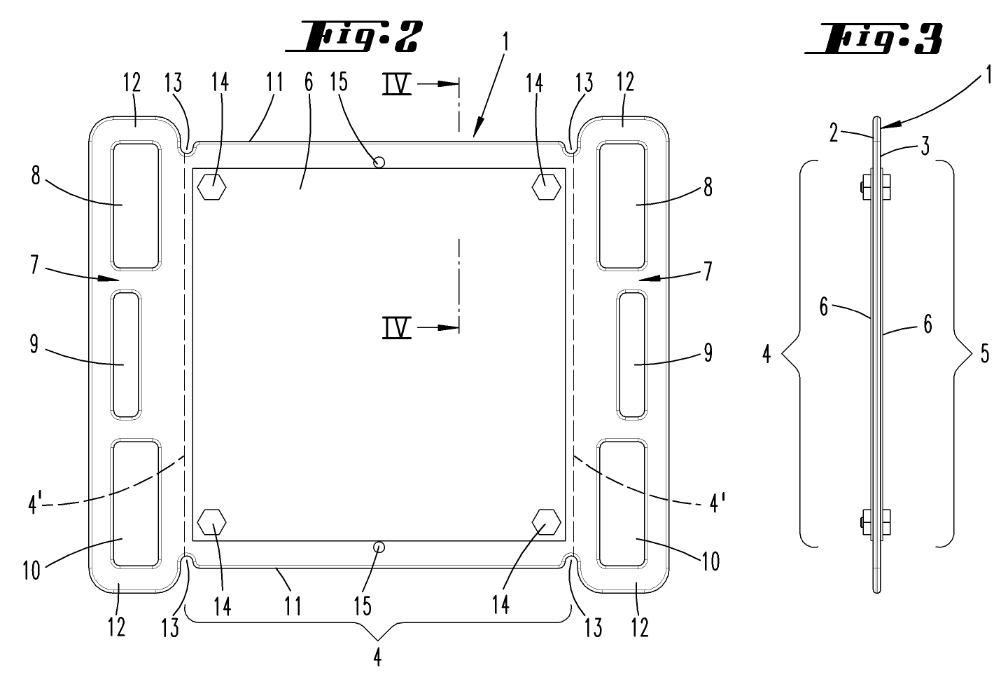

FIG. 2 shows the broad-side view of a substrate carrier;

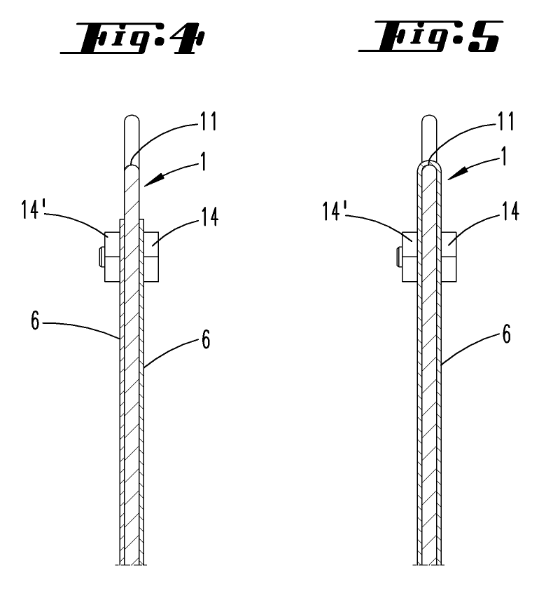

FIG. 3 shows the narrow-side view of a substrate carrier;

FIG. 4 shows the section according to line IV-IV in FIG. 2, wherein one substrate 6 is disposed on each of the two broad-side faces of the substrate carrier;

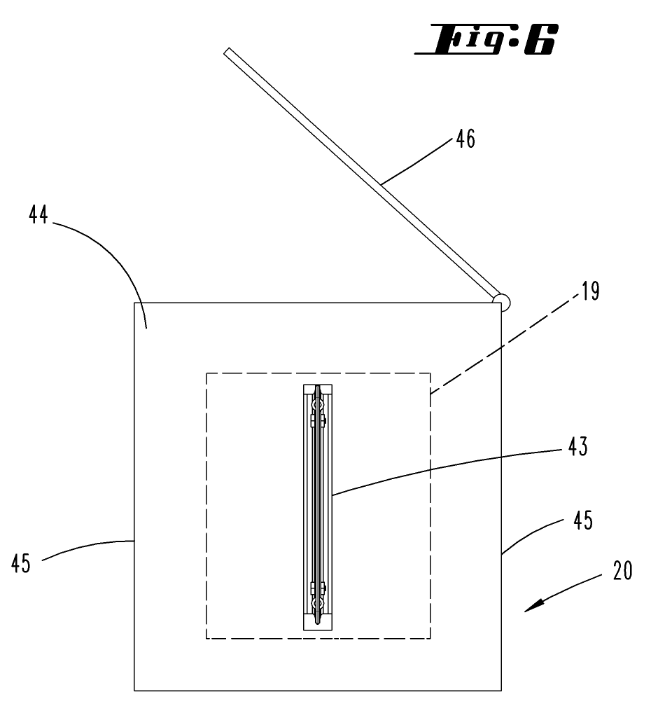

FIG. 5 shows an illustration according to FIG. 4, wherein the substrate carrier 1 carries a flexible substrate 6 which extends beyond the peripheral edge 11;

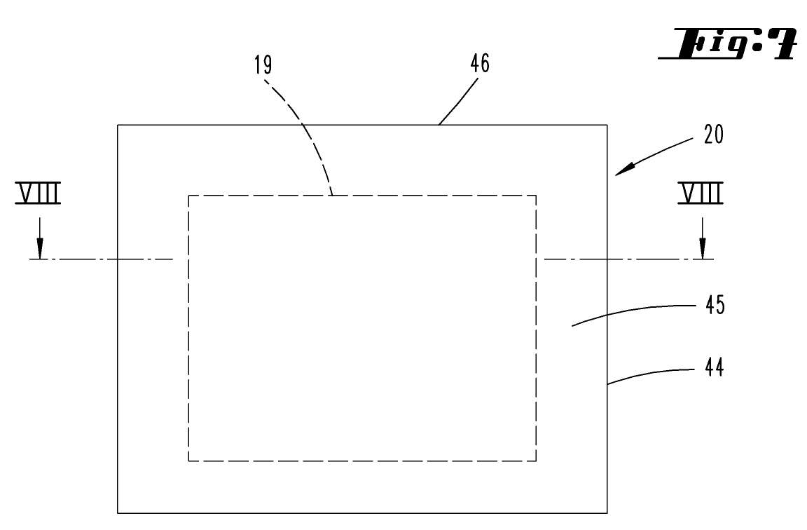

FIG. 6 shows a side view of a reactor housing 20 having an opened cover 46 and a processing-chamber housing 19 which is indicated as being disposed in the former;

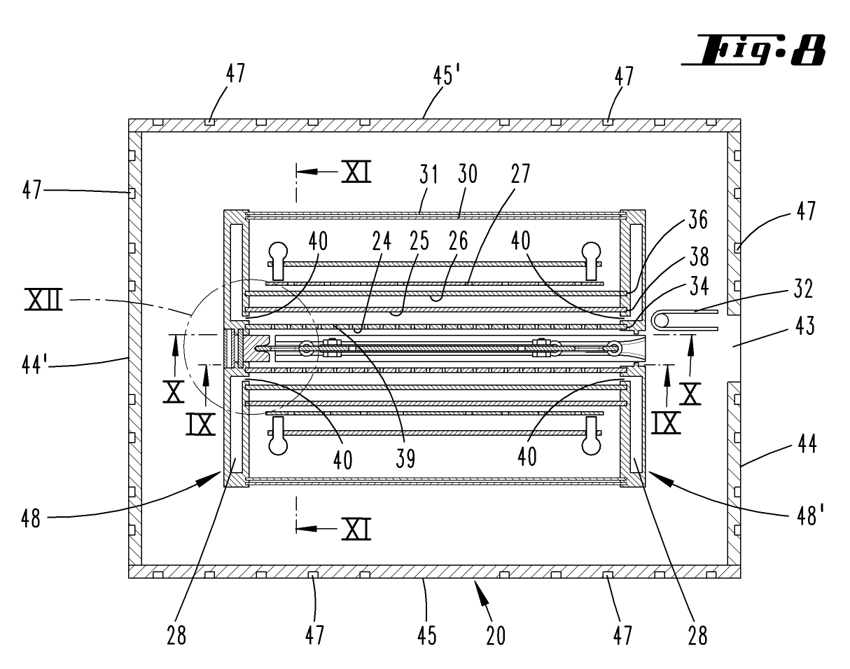

FIG. 7 shows the reactor housing 20 in the front view, having a closed cover and a processing-chamber housing 19 which is indicated as being disposed in the former;

FIG. 8 shows a section according to line VIII-VIII in FIG. 7;

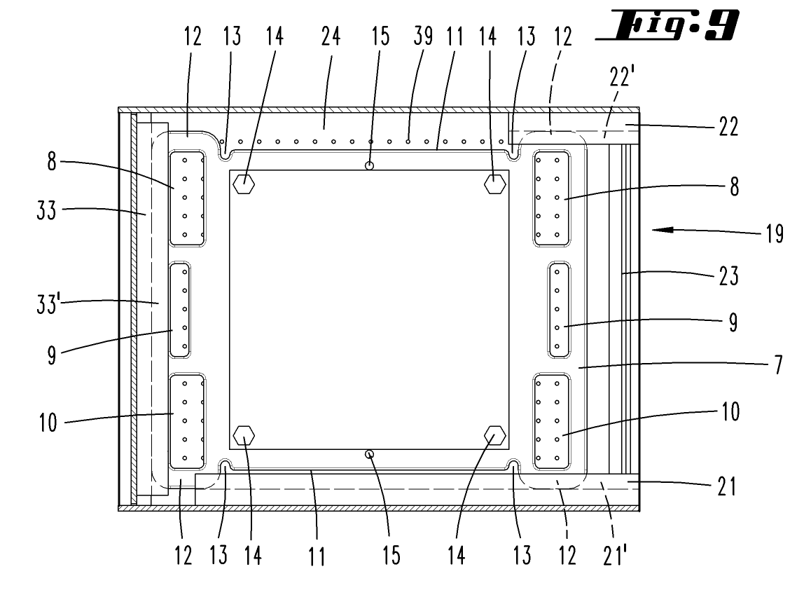

FIG. 9 shows a section according to line IX-IX in FIG. 8, viewed toward the substrate carrier 10 which is disposed in the processing-chamber housing 19;

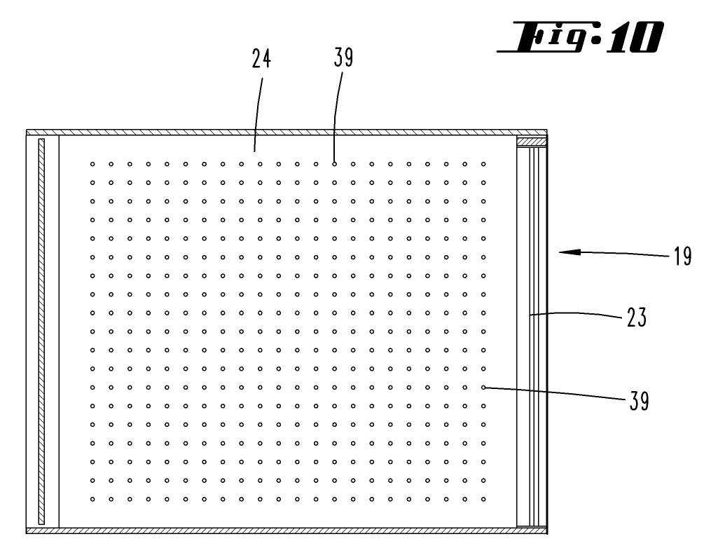

FIG. 10 shows a section according to line X-X in FIG. 8, viewed toward the gas-outlet plate 24;

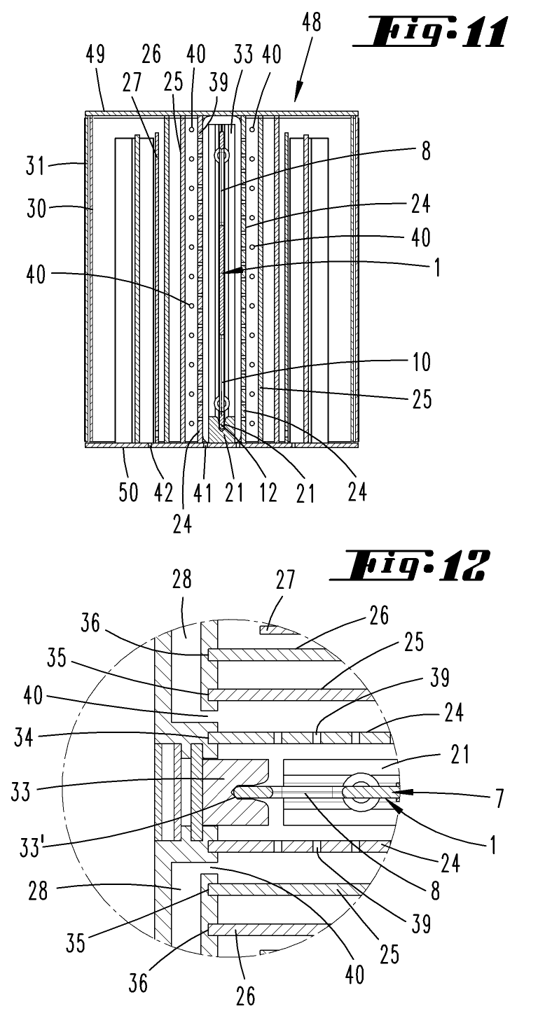

FIG. 11 shows a section according to line XI-XI in FIG. 8, viewed toward that side of a wall 48 of the processing-chamber housing 19 that is on the internal side of the processing-chamber housing;

FIG. 12 shows the enlarged detail XII in FIG. 8.

The reactor housing 20, illustrated in the drawings, has an ashlar-shaped design having four lateral walls 44, 44′; 45, 45′. The upper housing wall forms an upwardly pivotable cover 46. The cover 46 is closed during operation of the reactor. However, said cover 46 may be opened for maintenance purposes.

The lateral walls 44, 44′; 45, 45′ have ducts 47 through which a cooling liquid may flow so as to flush the walls 44, 44′; 45, 45′.

One of the lateral walls 44 has an opening 43 extending in the vertical direction. The opening 43 may be closed off in a gas-tight manner by way of a slide (not illustrated). Said opening 43 is a loading and unloading opening.

A processing-chamber housing 19, which likewise has a loading and unloading opening 23 extending in the vertical direction, is located within the reactor housing 20. The processing-chamber housing 19 in the interior thereof has a lower guide element 21 and an upper guide element 22. Both guide elements 21, 22 have the shape of a strip and have mutually facing grooves 21′, 22′. Two gas-inlet elements 24, 25 delimit vertical sides of a processing chamber. A substrate carrier 1 may be pushed through the vertical loading openings 23, 43 into the processing chamber. Herein, guide portions 12 of the substrate carrier 1 engage in grooves 21′, 22′ of the guide elements 21, 22. The substrate carrier 1 in the inserted state is located so as to be centered between the two gas-inlet elements 24. All six walls of the ashlar-shaped reactor housing 20 may have temperature-control ducts 47 through which a temperature-control liquid may flow, so as to either cool or heat the reactor walls.

The substrate carrier 1 is a flat body and has a substantially rectangular footprint. Said substrate carrier 1 has two broad-side faces 2, 3 which point away from one another and which each form one substrate-receiving zone 4, 5. The substrate-receiving zones 4, 5 which face away from one another have a substantially rectangular footprint.

FIG. 2 shows a broad-side face 2 having the substrate-receiving zone 4. The opposite broad-side face 3, having the substrate-receiving zone 5 thereof, is identically configured.

The flat body of which the substrate carrier 1 is composed has a material thickness which is less than 10 mm. The peripheral-edge length of the substrate carrier 1 is at least 100 mm.

The substrate-receiving zone 4, being of identical design to that of the substrate-receiving zone 5, has two first peripheries 4′. The first peripheries 4′ are imaginary lines. Moreover, the substrate-receiving zone 4 has second peripheries which are formed by peripheral edges 11 of the substrate carrier 1. The peripheral edges 11 are rounded.

Fixing elements 14 are located in corner regions of the substrate-receiving zones 4, 5. In the exemplary embodiment, the fixing elements 14 are illustrated as screws 14 having nuts 14′. However, the fixing elements 14, 14′ may also be clamping elements. A substantially rectangular substrate 6 is fastened onto one of the two substrate-receiving zones 4, 5 by means of these fixing elements 14, 14′. One substrate 6 is located on each one of the two broad-side faces 2, 3 such that the two substrate-receiving zones 4, 5 that face away from one another each carry one substantially rectangular substrate 6, wherein the substrates 6 are fastened to the substrate carrier 1 by way of the fixing elements 14, 14′. The substrates may be copper, aluminum, or nickel substrates, which are coated with nanotubes which are composed of carbon and which on the substrate surface grow transversely to the plane of extent.

The peripheral edges 11, forming a recess 13, transition to form protrusions 12. The latter herein are the abovementioned guide protrusions. The latter are formed by the two end portions of peripheral portions 7 of the substrate carrier 1. The peripheral portions 7 are directly adjacent to the peripheries 4′. A peripheral portion 7 which in each case forms one handling portion is adjacent to each of the two peripheries 4′ that face away from one another. The protrusions 12 extend in the plane of extent of the substrate carrier 1 and form peripheral portions which are spaced apart from the peripheral edge 11.

The two handling portions 7 of identical design not only have those protrusions 12 that protrude beyond the respective peripheral edge 11 of the substrate-receiving zone 4, 5, but also have window-type openings 8, 9, 10. The latter herein are three rectangular openings through which gas may flow, but which may also be used for manual handling. To this end, the openings 8, 9, 10 are used as gripping openings. The central rectangular opening may be gripped by a gripper of a manipulator arm.

As is shown in FIG. 1, the substrate carrier 1 has various bores 15, 16. The bores 16 serve for fixing the fixing elements 14 on the substrate carrier 1. The bore may be likewise used as a fastening bore for a fixing element. However, the bore 15 may have a stop element.

FIG. 4 shows a first type of use of the substrate carrier 1, in which the substrate carrier 1 on each of its broad-side faces 2, 3 that face away from one another carries one substrate 6.

FIG. 5 shows a second type of use of the substrate carrier 1. The substrate 6 that is carried by the substrate carrier 1 herein is flexible. Said substrate 6 has two end portions which are each assigned to one of the two substrate-receiving zones 4, 5 and are fastened thereto. A central portion of the substrate 6 bears on the rounded peripheral edge 11. The substrate 6 is thus folded around the peripheral edge 11 in a U-shaped manner.

The substrate may be a thin copper, nickel, or aluminum foil. A process gas (H₂, NH₃, AR, N₂, CH₄, C₂H₄, C₂H₂, or C₆H₆) is directed into the processing chamber by way of the gas-inlet elements 24. By way of a chemical, in particular a catalytic, reaction, the hydrocarbons are deconstructed to form carbon. Herein, this may be a pyrolytic surface reaction. Graphene structures are deposited on the substrate, or nanotubes are deposited thereon

The interior space of the reactor housing 20 may be evacuated. A vacuum pump (not illustrated) serves this purpose.

The processing-chamber housing 19 has six walls which run parallel with assigned walls 44, 44′; 45, 45′, or 48, 31, 49, 50, respectively, of the reactor housing 20. The walls of the processing-chamber housing 19 are spaced apart from the walls of the reactor housing 20.

A wall 48 of the processing-chamber housing 19 forms cavities 28. These cavities 28 are a component part of a gas-infeed installation. The cavity 28 may be fed from the outside with a process gas which, as will be explained in more detail hereunder, by way of openings may enter the interior of the processing-chamber housing 19. Two mutually opposite housing walls 48, 48′ which are configured in multiple parts are provided. The housing wall 48′ forms the abovementioned loading opening 23. Both housing walls 48, 48′ on that side thereof that faces the interior of the processing-chamber housing 19 have a multiplicity of retaining clearances 34 to 38, running so as to be mutually parallel and in the vertical direction. The retaining clearances 34 to 38 are each formed by vertical grooves. The peripheries of plate-shaped elements 24, 25, 26, 30, 31 of the processing-chamber housing 19 are located in the retaining clearances 34 to 38. The processing-chamber housing 19 in relation to a central plane has symmetrically folding design. The substrate carrier 1, or the retaining elements 21, 22, and 33 which each have grooves 21′, 22′, and 33′ for mounting the substrate carrier 1, respectively, is/are located in this central plane.

One gas-inlet element is located on each of the two broad sides of the substrate carrier 1, each gas-inlet element being in the form of a shower head. The respective shower head is formed by a gas-inlet plate 24 which is made of quartz and by way of two peripheries that face away from one another is pushed into one retaining clearance 34 for each of the latter. The gas-inlet plate 24, for exiting a process gas that is transported by a carrier gas into the processing chamber which is disposed between the two mutually opposite gas-inlet plates 24, has a multiplicity of gas-exit openings 39 that are disposed so as to be uniformly distributed across the area of the gas-inlet plate 24.

A volume which is supplied by the abovementioned gas-infeed openings 40 with process gas or carrier gas, respectively, in relation to the position of the processing chamber, is located to the rear of the gas-inlet plate 24, said process gas or carrier gas being able to enter the processing chamber through the gas-exit openings 39.

A rear wall 25 of the gas-inlet element extends so as to be parallel with the gas-inlet plate 24. The lateral peripheries of the rear wall 25 are pushed into the retaining clearances 35.

A further quartz plate 26, the peripheries of which are pushed into retaining clearances 36, is located to the rear of the rear wall 25.

A resistance heater 27 is located to the rear of the quartz plate 26. Said resistance heater 27 herein is a metal plate which runs in a meandering manner and through which a current may flow so that the heating element 27 may be heated. The gas-inlet plate 24, rear wall 25, and plate 26, all composed of quartz, are substantially transparent to the infrared radiation that is generated by the heating element 27 and that can heat the substrate 6 to a substrate temperature of approximately 1000° C. Connector contacts for providing power to the two heating elements 27 are provided.

A shield plate 29 which may also act as a reflector is located to the rear of the heating element 27. This shield plate 29 is fastened to the mounting of the heating element 27, said mounting also serving for supplying power.

The peripheries of a reflector 30 and of a rear wall 31 are pushed into the retaining clearances 37, 38 which run parallel with the vertical peripheries of the walls 48, 48′.

The processing-chamber housing 19 has a ceiling 49 which is removable. If and when the ceiling 49 is removed with the cover 46 being open, the plates 24, 25, 26, 37, 38 may be pulled upward and out of the processing-chamber housing 19. Said plates may then be cleaned or replaced. The plates 24, 25, 26, 30, 31 may be pushed back into their assigned retaining clearances 34 to 38 thereof in a likewise simple manner.

The base plate 50 has gas-exit openings 41 from which the gas that has flown through the opening 39 into the processing chamber may exit from the processing chamber. Furthermore, gas-exit openings 42 which serve as exit for a purging gas which is fed into the space beyond the two shower heads in which the heating element 27 is located are provided.

The abovementioned guide elements 21, 22, 33 each have one groove-shaped clearance 21′, 22′, 33′ which by way of a rounded mouth region form pilot flanks for the peripheral edge of the substrate carrier 1.

It can be seen from FIG. 9 that the peripheral edges 11 in the pushed-in state sit freely. The latter are spaced apart from the guide elements 21 and 22, respectively.

A reflector 32 that is rotatable about a vertical axis is located ahead of the loading opening 23 of the processing-chamber housing 19. During operation of the processing chamber, the rotatable reflector 32 assumes a position such that the reflecting surface of said reflector 32 lies in front of the loading opening 23. If the processing chamber is to be loaded or unloaded, respectively, the rotatable reflector 32 is pivoted such that the two mutually aligned openings 23, 43 are free for passing through the substrate carrier 1.

The information above serves for explaining the inventions as comprised in their entirety by the application, which in each case individually refine the prior art at least by way of the combinations of features hereunder, namely:

A device characterized in that the first broad-side face 2 and the second broad-side face 3 in each case include one substrate-receiving zone 4, 5 in which fixing elements 14, 14′, 15, by way of which in each case one substrate 6 or portions of a substrate 6 is/are fastenable on the broad-side face 2, 3, are provided.

A device characterized in that the substrate carrier 1 is a flat body, in particular composed of quartz, and the substrate-receiving zones 4, 5 have a substantially rectangular footprint, wherein the body has in particular a thickness of 10 mm maximum and an edge length of at least 100 mm.

A device characterized in that the substrate-receiving zone 4, 5 has two peripheries 4′ that face away from one another and which are adjoined in each case, in particular in a materially integral manner, by a handling portion 7.

A device characterized in that the handling portion 7 has window-type, in particular rectangular, openings 8, 9, 10.

A device characterized in that the handling portion 7 has protrusions 12 which protrude beyond second peripheries 11 of the substrate-receiving zone 4, which extend transversely to the first peripheries 4′.

A device characterized in that at least one second periphery 11 of the substrate-receiving zone 4, 5 is, in particular, a rounded peripheral edge of the substrate carrier 1, around which a flexible substrate 6 is placeable in such a manner that the substrate 6 is fastenable by way of two portions on in each case one substrate-receiving zone 4, 5.

A device characterized in that the second periphery 11 runs in a recessed manner in relation to a peripheral edge of the protrusion 12 which runs substantially parallel with the second periphery 11.

A device characterized in that the reactor housing 20 has guide elements 21, 22, 33 along which the substrate carrier 1 is displaceable by way of the protrusions 12 thereof, wherein it is provided in particular that only the protrusions 12 engage in grooves 21′, 22′, 33′ formed by the guide elements 21, 22.

A device characterized in that the substrate carrier 1, in a vertical orientation, is insertable into the intermediate space between two gas-inlet elements 24 of the reactor housing 20 through a loading opening 23 which extends in the vertical direction.

All features disclosed (per se, or else in mutual combination) are relevant to the invention. Herein, the entire disclosed content of the associated/appended priority documents (copy of the preliminary application) is included in the disclosure of the application, also for the purpose of conjointly including features of that document in claims of the present application. The dependent claims by way of the features thereof characterize individual inventive refinements of the prior art, in particular so as to perform divisional applications based on these claims.

### LIST OF REFERENCE SIGNS

1 Substrate carrier
2 Broad-side face
3 Broad-side face
4 Substrate-receiving zone
4′ Periphery
5 Substrate-receiving zone
5′ Periphery
6 Substrate
7 Handling portion/Peripheral portion
8 Opening
9 Opening
10 Opening
11 Peripheral edge
12 Protrusion/Guide portion
13 Recess
14 Fixing element/Screw
14′ Fixing element/Nut
15 Bore
16 Bore
19 Processing-chamber housing
20 Reactor housing
21 Guide element
21′ Groove, clearance
22 Guide element
22′ Groove
23 Loading/Unloading opening
24 Gas-inlet element, gas-inlet plate
25 Rear wall
26 Quartz plate
27 Heating element
28 Gas-infeed installation; cavity
29 Shield plate
30 Reflector
31 Rear wall
32 Rotatable reflector
33 Retaining element
33′ Groove, clearance
34 Retaining clearance
35 Retaining clearance
36 Retaining clearance
37 Retaining clearance
38 Retaining clearance
39 Gas-exit opening
40 Gas-infeed opening
41 Gas-exit opening
42 Gas-exit opening
43 Loading opening
44 Wall
44′ Wall
45 Wall
45′ Wall
46 Wall, cover
47 Temperature-control duct
48 Housing wall
48′ Housing wall
49 Ceiling plate
50 Base plate

1. A substrate carrier having a first broadside face (2) and a second broadside face (3) facing away from the first broadside face (2), wherein the first broadside face (2) includes a first substrate-receiving zone (4) in which a first plurality of fixing elements (14, 14′, 15) are configured to fasten a first substrate (6) or a first portion of the first substrate (6) onto the first broadside face (2), and the second broadside face (3) includes a second substrate-receiving zone (5) in which a second plurality of fixing elements (14, 14′, 15) are configured to fasten a second substrate (6) or a second portion of the first substrate (6) onto the second broadside face (3), characterized in that the substrate carrier (1) is a solid flat body, and the first and second substrate-receiving zones (4, 5) are bounded by two first peripheries (4′) that face away from one another, and two second peripheries (11) that extend transverse to the first peripheries (4′), wherein adjoined to each of the first peripheries (4′) is a handling portion (7) which comprises (i) two protrusions (12) that each protrude beyond a corresponding one of the second peripheries (11), or (ii) window-type openings (8, 9, 10).

2. The substrate carrier of claim 1, the substrate carrier (1) is composed of quartz.

3. The substrate carrier of claim 1, wherein the first and second substrate-receiving zones (4, 5) have a substantially rectangular footprint.

4. The substrate carrier of claim 1, wherein the solid flat body has a maximum thickness of 10 mm, and an edge length of at least 100 mm.

5. The substrate carrier of claim 1, wherein the handling portion (7) has window-type openings (8, 9, 10).

6. The substrate carrier of claim 1, wherein the first broadside face (2) is configured to receive the first portion of the first substrate (6), the second broadside face (3) is configured to receive the second portion of the first substrate (6), and a rounded peripheral edge of the substrate carrier (1) is configured to receive a third portion of the first substrate (6), the third portion being flexible.

7. The substrate carrier of claim 1, wherein at least one of the second periphery peripheries (11) is situated in a recessed manner with respect to a peripheral edge of a corresponding one of the protrusions (12), and the at least one of the second peripheries (11) is further situated in a parallel manner with respect to the peripheral edge of the corresponding one of the protrusions (12).

8. The substrate carrier of claim 1, wherein the protrusions (12) of the substrate carrier (1) are configured to be displaceable along guide elements (21, 22, 33) of a reactor housing (20).

9. The substrate carrier of claim 8, wherein the substrate carrier (1) contacts the reactor housing (20) only along regions where the protrusions (12) engage in grooves (21′, 22′, 33′) formed by the guide elements (21, 22, 33) of the reactor housing (20).

10. The substrate carrier of claim 8, wherein the substrate carrier (1), while oriented in a vertical manner, is insertable into an intermediate space between two gas-inlet elements (24) of the reactor housing (20) through a loading opening (23) of the reactor housing (20) which extends in a vertical direction.
